(19) United States
(12) Patent Application Publication
(10) Pub. No.: US 2025/0338697 A1
(43) Pub. Date: Oct. 30, 2025

(54) MICRO LED ARRAY AND MICRO LED DISPLAY PANEL

(71) Applicant: JADE BIRD DISPLAY (SHANGHAI) LIMITED, SHANGHAI (CN)

(72) Inventors: Weisin TAN, Shanghai (CN); Zhichen GU, Shanghai (CN); Qunchao XU, Shanghai (CN)

(21) Appl. No.: 19/190,535

(22) Filed: Apr. 25, 2025

(30) Foreign Application Priority Data
Apr. 26, 2024 (WO) PCT/CN2024/090034

(51) Int. Cl. H10H 29/85; H10H 29/49

(52) U.S. Cl. CPC H10H 29/8581; H10H 29/49

(57) ABSTRACT

A micro LED array includes a plurality of micro LED structures, wherein each of the micro LED structures includes: a mesa structure; a bonding layer provided at a bottom of the mesa structure to bond the mesa structure with an integrated circuit (IC) backplane; and a first thermal conductive layer formed surrounding sidewalls of the mesa structure and the bonding layer, wherein a material of the first thermal conductive layer is an electrically insulative material with high thermal conductivity.

### CROSS-REFERENCE TO RELATED APPLICATIONS

The present disclosure claims the benefits of priority to PCT Application No. PCT/CN 2024/090034, filed on Apr. 26, 2024, which is incorporated herein by reference in its entirety.

### TECHNICAL FIELD

The present disclosure generally relates to micro LED manufacturing technology, and more particularly, to a micro LED array and a micro LED display panel.

### BACKGROUND

Inorganic micro pixel light emitting diodes, also referred to as micro light emitting diodes, micro LEDs, or u-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

Generally, a micro LED display panel includes an array of micro LEDs. Each micro LED may generate heat when emitting light. However, high temperature may impact the performance of the micro LED display panel. Therefore, there is a challenge to improve a heat dissipation effect.

### SUMMARY OF THE DISCLOSURE

Embodiments of the present disclosure provide a micro LED array. The micro LED array includes a plurality of micro LED structures, each of the a micro LED structures including: a mesa structure; a bonding layer provided at a bottom of the mesa structure to bond the mesa structure with an integrated circuit (IC) backplane; and a first thermal conductive layer formed surrounding sidewalls of the mesa structure and the bonding layer, wherein a material of the first thermal conductive layer is electrically insulative material with high thermal conductivity.

Embodiments of the present disclosure also provide a micro LED display panel. The micro LED display panel includes: an integrated circuit (IC) backplane comprising a bottom pad array, the bottom pad array comprising a plurality of bottom pads; and an above-described micro LED array formed on the IC backplane. One micro LED structure of the plurality of micro LED structures is electrically connected with one bottom pad of the plurality of bottom pads.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural cross-sectional diagram of an exemplary micro LED array, according to some embodiments of the present disclosure.

FIG. 2 illustrates a structural diagram of a top view of the micro LED array shown in FIG. 1 with a top conductive layer removed, according to some embodiments of the present disclosure.

FIG. 3 illustrates a structural cross-sectional diagram of another exemplary micro LED array, according to some embodiments of the present disclosure.

FIG. 4 illustrates a structural cross-sectional diagram of another exemplary micro LED array, according to some embodiments of the present disclosure.

FIG. 5 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED array having improved heat dissipation efficiency.

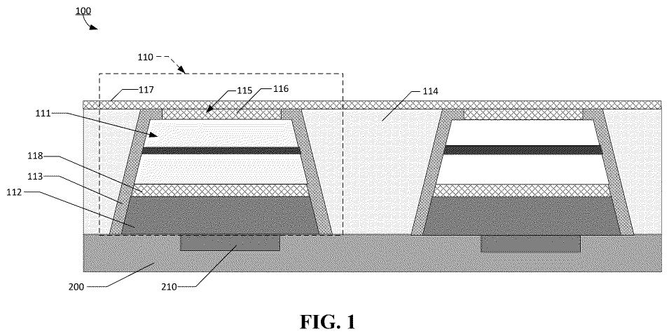

FIG. 1 illustrates a structural cross-sectional diagram of an exemplary micro LED array 100, according to some embodiments of the present disclosure. FIG. 1 shows two complete micro LED structures 100, and only one micro LED structure 110 is described for illustrative purposes. Accordingly, it can be understood that micro LED array 100 may include a plurality of micro LED structures 110. Referring to FIG. 1 micro LED structure 110 includes a mesa structure 111 and a bonding layer 112. Bonding layer 112 is provided at a bottom of mesa structure 111 to bond mesa structure 111 with a bottom pad 210 on an integrated circuit (IC) backplane 200. IC backplane 200 is provided at a bottom of micro LED array 100 for providing control of micro LED array 100. A material of bonding layer 112 is metal. For example, the material of bonding layer 112 may include: AI, Au, Rh, Ag, Cr, Ti, Pt, Sn, Cu, etc. The material may also include metal alloys, for example, AuSn, TiW, NiSn, and the like. In some embodiments, bonding layer 112 can further configured as a reflector to reflect light upwards. Therefore, the light emission efficiency of micro LED structure 110 can be further improved.

Micro LED structure 110 further includes a first thermal conductive layer 113 formed surrounding sidewalls of mesa structure 111 and bonding layer 112. A material of first thermal conductive layer 113 is an electrically insulative material with high thermal conductivity, so that first thermal conductive layer 113 can radiate heat generated by mesa structure 111. In some embodiments, a thermal conductivity of the insulator material of first thermal conductive layer 113 is greater than 300W/mK. For example, the material of first thermal conductive layer 113 may be AlN, SiC, Boron, Nitride, diamond, diamond-like carbon, and the like.

In some embodiments, micro LED array 100 further includes a second thermal conductive layer 114 filled between adjacent ones of micro LED structures 110. A material of second thermal conductive layer 114 is a material with high thermal conductivity, so that second thermal conductive layer 114 can further radiate the heat to the air. For example, a thermal conductivity of the material of second thermal conductive layer 114 is greater than 300W/mK. In some embodiments, the material of second thermal conductive layer 114 is electrically insulative, such as, AlN, SiC, Boron, Nitride, diamond, or diamond-like carbon. In some embodiments, the material of second thermal conductive layer 114 is electrically conductive, such as, Ag, Cu, Al, Graphite, Graphene, or the like.

In some embodiments, as shown in FIG. 1 first thermal conductive layer 113 is further provided on a portion of a top surface of mesa structure 111 and defines an opening 115 on the top surface of mesa structure 111. A first top conductive layer 116 is further provided to fill opening 115. In some embodiments, first top conductive layer 116 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, as shown in FIG. 1 micro LED array 100 further includes a second top conductive layer 117 provided on a top of micro LED structure 110, and respective first top conductive layers 116 of the plurality of micro LED structures 110 are interconnected to form a whole conductive layer. In some embodiments, second top conductive layer 117 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like. A material of first top conductive layer 116 and a material of second top conductive layer can be the same or different.

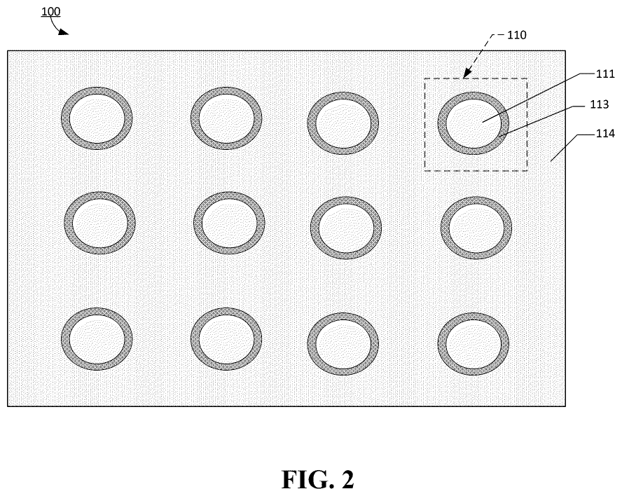

FIG. 2 illustrates a structural diagram of a top view of the micro LED array 100 shown in FIG. 1 with a second top conductive layer 117 removed for illustrative purposes, according to some embodiments of the present disclosure. Referring to FIG. 2 in this example, micro LED array 100 includes a 4×3 micro LED structures 110. It can be understood that a micro LED array can include different numbers of micro LED structures 110. As shown in FIG. 2 each mesa structure 111, which may generate heat when emitting light, is surrounded by first thermal conductive layer 113, and second thermal conductive layer 114 is filled between adjacent ones of micro LED structures 110. With the high thermal conductivity of the first thermal conductive layer 113 and second thermal conductive layer 114, the heat dissipation effect can be improved.

Referring back to FIG. 1 in some embodiments, micro LED structure 110 further includes a bottom conductive layer 118 provided between mesa structure 111 and bonding layer 112 to provide an ohmic conduct between mesa structure 111 and bonding layer 112. In some embodiments, bottom conductive layer 118 includes an omni-directional reflector (ODR) structure with high reflectivity. In some embodiments, bottom conductive layer 118 is a TCO (transparent conductive oxide) thin film, for example, an ITO (Indium Tin Oxide) film, an AZO (Antimony doped Zinc Oxide) film, an ATO (Antimony doped Tin Oxide) film, an FTO (Fluorine doped Tin Oxide) film, and the like.

In some embodiments, mesa structure 111 includes a P-N structure. For example, mesa structure 111 includes a first semiconductor layer, a second semiconductor layer, and a light emitting layer provided between the first semiconductor layer and the second semiconductor layer. The first semiconductor layer is provided on the light emitting layer, and the light emitting layer is provided on the second semiconductor layer. Bonding layer 112 is provided facing a bottom surface of the second semiconductor layer. The light emitting layer can emit red light, green light, or blue light. In some embodiments, an area of a top surface of mesa structure 111 is smaller than an area of bottom surface of mesa structure 111. In some embodiments, the first semiconductor layer is an N-type semiconductor layer, and the second semiconductor layer is a P-type semiconductor layer.

In some embodiments, IC backplane 200 includes an array of bottom pads 210. Each bottom pad 210 corresponds to one micro LED structure 110. In some embodiments, bottom pad 210 is a Cu-pad.

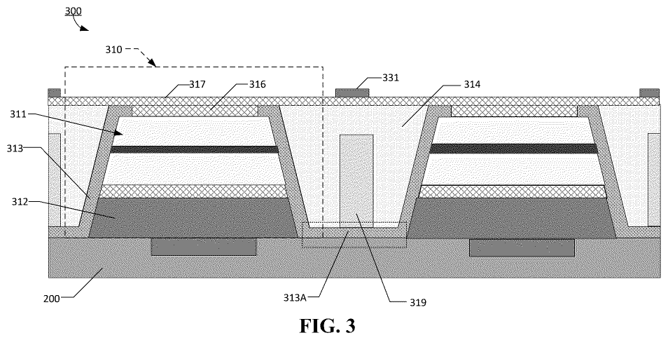

FIG. 3 illustrates a structural cross-sectional diagram of another exemplary micro LED array 300, according to some embodiments of the present disclosure. FIG. 3 shows two complete micro LED structures 310, and only one micro LED structure 310 is described for illustrative purposes. Accordingly, it can be understood that micro LED array 300 may include a plurality of micro LED structures 310. Referring to FIG. 3, similar to micro LED array 100 shown in FIG. 1 micro LED structure 310 includes a mesa structure 311 and a bonding layer 312. Bonding layer 312 is provided at a bottom of mesa structure 311 to bond mesa structure 311 with an integrated circuit (IC) backplane 200. Micro LED structure 310 further includes a first thermal conductive layer 313 formed surrounding sidewalls of mesa structure 311 and bonding layer 312. In this example, first thermal conductive layer 313 is further formed on a top surface of IC backplane 200 between adjacent ones of micro LED structures 310. For example, first thermal conductive layer 313 includes a portion 313A provided on IC backplane 200 between adjacent ones of micro LED structures 310. Accordingly, first thermal conductive layer 313 is continuously formed in this example, and can further radiate heat from IC backplane 200.

As shown in FIG. 3, micro LED array 300 further includes a second thermal conductive layer 314 filled between adjacent ones of micro LED structures 310. In some embodiments, micro LED array 300 further includes an isolation structure 319 provided between adjacent ones of micro LED structures 310 to isolate light and reduce crosstalk between the adjacent ones of micro LED structures 310. In some embodiments, the material of second thermal conductive layer 314 is electrically insulative. A material of isolation structure 319 can be electrically conductive or insulative. In some embodiments, when the material of second thermal conductive layer 314 is electrically conductive., a material of isolation structure 319 is electrically insulative.

Referring to FIG. 3, micro LED array 300 further includes a second top conductive layer 317 provided on a top of micro LED structure 310. As a result, a first top conductive layer on a top surface of mesa structure 311 and respective first top conductive layers 316 of the plurality of micro LED structures 310 are interconnected to form a whole conductive layer. In this example, micro LED array 300 further includes a plurality of top contact 331 provided on second top conductive layer 317 and between adjacent ones of micro LED structures 310, and the plurality of top contacts are interconnected to improve electrical conductivity of second top conductive layer 317.

Description of other features of micro LED array 300 may be found by referring to such features described above with reference to FIG. 1 which will not be repeated here.

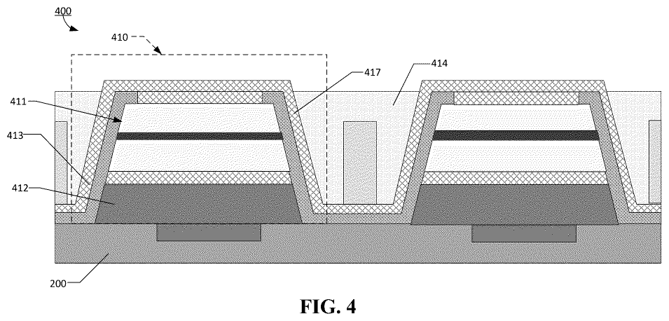

FIG. 4 illustrates a structural cross-sectional diagram of another exemplary micro LED array, according to some embodiments of the present disclosure. FIG. 4 shows two complete micro LED structures 410, and only one micro LED structure 410 is described for illustrative purposes. Accordingly, it can be understood that micro LED array 400 may include a plurality of micro LED structures 410. Referring to FIG. 4, similar to micro LED array 100 shown in FIG. 1 and micro LED array 300 shown in FIG. 3, micro LED structure 410 includes a mesa structure 411 and a bonding layer 412. Bonding layer 412 is provided facing a bottom of mesa structure 411 to bond mesa structure 411 with an integrated circuit (IC) backplane 200. Micro LED structure 410 further includes a first thermal conductive layer 413 formed surrounding sidewalls of mesa structure 411 and bonding layer 412. First thermal conductive layer 413 is further formed on a top surface of IC backplane 200 between adjacent ones of micro LED structures 410. In this example, micro LED structure 410 includes a top conductive layer 417 provided on a top surface of mesa structure 411 and on first thermal conductive layer 413.

Referring to FIG. 4, in this example, micro LED array 400 further includes a second thermal conductive layer 414 filled between adjacent ones of micro LED structures 410 and on part of top conductive layer 417.

Description of other features of micro LED array 400 may be found by referring to such features described above with reference to FIG. 1 and FIG. 3, which will not be repeated here.

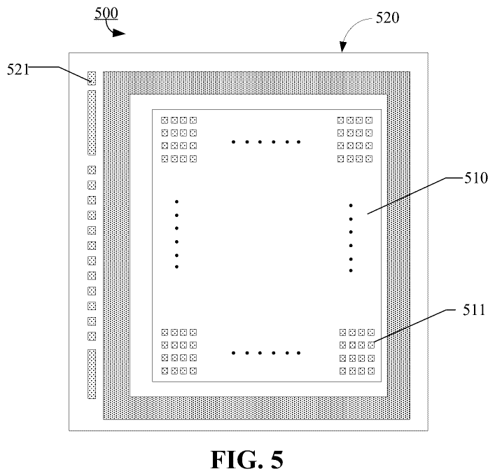

FIG. 5 illustrates a structural diagram showing a top view of a micro LED display panel 500, according to some embodiments of the present disclosure. Referring to FIG. 5, micro LED display panel 500 includes a micro LED array 510 (for example, micro LED array 100, micro LED array 300, or micro LED array 400) and an IC (integrated circuit) backplane 520. Micro LED array 510 is located on IC backplane 520 to form an image display area of micro LED display panel 500. The rest of the area on IC backplane 520 not covered by micro LED array 510 is formed as a non-functional area. IC backplane 520 is formed at the back surface of micro LED array 510 with a part extending outside of, i.e., not covered by, micro LED array 510. Micro LED array 510 includes a plurality of micro LEDs 511 (for example, micro LED structure 110, micro LED structure 310, or micro LED structure 410) provided in micro LED array 510. IC backplane 520 is configured to control the plurality of micro LEDs 511. IC backplane 520 may include a bottom pad array (not shown) corresponding to micro LED array 510. The bottom pad array includes a plurality of bottom pads (for example, bottom pad 210 in FIG. 1), and one bottom pad corresponds to one micro LED 511. One micro LED of the plurality of micro LEDs is electrically connected with one bottom pad of the plurality of the bottom pad.

In some embodiments, a top conductive layer (for example, second top conductive layer 117, second top conductive layer 317, or second top conductive layer 417) of the micro LED is interconnected with each of the plurality of micro LEDs. That is, the top conductive layer is continuously formed on a top of micro LED array 510, and connected with every micro LED 511.

In some embodiments, IC backplane 520 further includes a top connected pad 521. The top conductive layer is connected with top connected pad 521, and further may connect to an external circuit.

Each micro LED structure herein (e.g., micro LED structure 110, micro LED structure 310, or micro LED structure 410) has a very small volume. The micro LED structure can be applied in a micro LED display panel. The light emitting area of the micro LED display panel, e.g., micro LED display panel 500, is very small, such as 1 mm×1 mm, 3 mm×5 mm, etc. In some embodiments, the light emitting area is the area of micro LED array 510 in micro LED display panel 500. The micro LED display panel includes one or more micro LED s that form a pixel array in which the micro LEDs of micro LED array 510 are pixels, such as a 1600×1200, 680×480, or 1920×1080-pixel array. The diameter of each micro LED is in the range of about 200 nm to 2 μm. An IC backplane, e.g., IC backplane 520, is formed at the back surface of micro LED array 510 and is electrically connected with micro LED array 510. IC backplane 520 acquires signals such as image data from outside via signal lines to control corresponding micro LEDs 511 to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED array, comprising a plurality of micro LED structures, each of the micro LED structures comprising:
a mesa structure;
a bonding layer provided at a bottom of the mesa structure to bond the mesa structure with a bottom pad on an integrated circuit (IC) backplane; and
a first thermal conductive layer formed surrounding sidewalls of the mesa structure and the bonding layer, wherein a material of the first thermal conductive layer is an electrically insulative material with high thermal conductivity.

2. The micro LED array according to claim 1, wherein a thermal conductivity of the electrically insulative material of the first thermal conductive layer is greater than 300W/mK.

3. The micro LED array according to claim 2, wherein the material of the first thermal conductive layer is AlN, SiC, Boron, Nitride, diamond, or diamond-like carbon.

4. The micro LED array according to claim 1, further comprising a second thermal conductive layer filled between adjacent ones of micro LED structures, wherein a material of the second thermal conductive layer is a material with high thermal conductivity.

5. The micro LED array according to claim 4, wherein a thermal conductivity of the material of the second thermal conductive layer is greater than 300W/mK.

6. The micro LED array according to claim 5, wherein the material of the second thermal conductive layer is electrically insulative.

7. The micro LED array according to claim 6, wherein the material of the second thermal conductive layer is AlN, SiC, Boron, Nitride, diamond, or diamond-like carbon.

8. The micro LED array according to claim 5, wherein the material of the second thermal conductive layer is electrically conductive.

9. The micro LED array according to claim 8, wherein the material of the second thermal conductive layer is Ag, Cu, Al, Graphite, or Graphene.

10. The micro LED array according to claim 1, further comprising an isolation structure provided between adjacent ones of micro LED structures to isolate light and reduce crosstalk between adjacent ones of micro LED structures.

11. The micro LED array according to claim 1, wherein the first thermal conductive layer is further provided on a portion of a top surface of the mesa structure and forms an opening on the top surface of the mesa structure.

12. The micro LED array according to claim 11, further comprising a top conductive layer provided in the opening.

13. The micro LED array according to claim 1, wherein the first thermal conductive layer is further formed on a top surface of the IC backplane between adjacent ones of micro LED structures.

14. The micro LED array according to claim 13, further comprising a top conductive layer provided on a top surface of the mesa structure and on the first thermal conductive layer.

15. The micro LED array according to claim 1, further comprising a top conductive layer provided on a top of the micro LED structure, and respective top conductive layers of the plurality of micro LED structure are interconnected.

16. The micro LED structure according to claim 15, further comprising a plurality of top contacts provided on the top conductive layer and between adjacent ones of micro LED structures, wherein the plurality of top contacts are interconnected.

17. A micro LED display panel, comprising:
an integrated circuit (IC) backplane comprising a bottom pad array, the bottom pad array comprising a plurality of bottom pads; and
a micro LED array comprising a plurality of micro LED structures formed on the IC backplane, wherein each of the micro LED structures comprises:
a mesa structure;
a bonding layer provided at a bottom of the mesa structure to bond the mesa structure with a bottom pad on an integrated circuit (IC) backplane; and
a first thermal conductive layer formed surrounding sidewalls of the mesa structure and the bonding layer, wherein a material of the first thermal conductive layer is an electrically insulative material with high thermal conductivity; and
wherein one micro LED structure of the plurality of micro LED structures is electrically connected with one bottom pad of the plurality of bottom pads.
